(19) United States
(12) Patent Application Publication
(10) Pub. No.: US 2015/0041182 A1
(43) Pub. Date: Feb. 12, 2015

(54) PACKAGE SUBSTRATE AND CHIP PACKAGE USING THE SAME

(71) Applicant: NANYA TECHNOLOGY CORP., Tao-Yuan Hsien (TW)

(72) Inventors: Po-Chun Lin, Changhua County (TW); Han-Ning Pei, Taipei City (TW)

(21) Appl. No.: 14/523,955

(22) Filed: Oct. 27, 2014

Related U.S. Application Data
(62) Division of application No. 13/659,916, filed on Oct. 25, 2012.

(51) Int. Cl. H05K 1/02

(52) U.S. Cl. CPC H05K 1/02
USPC 174/250; 428/172

(57) ABSTRACT

A package substrate is disclosed. The package substrate includes a base layer and a dam structure or a dent structure on at least one side of the base layer. The base layer may be a CCL core, a molding compound, or an epoxy base.

### CROSS REFERENCE TO RELATED APPLICATIONS

This application is a division of U.S. application Ser. No. 13/659,916 filed Oct. 25, 2012, which is included in its entirety herein by reference.

### BACKGROUND OF THE INVENTION

1. Field of the Invention

The present invention relates to semiconductor devices. More particularly, the present invention relates to a package substrate and a chip package structure.

2. Description of the Prior Art

In the integrated circuit (IC) packaging industry, there is a continuous desire to provide higher and higher density IC packages for semiconductor die having increasing numbers of input/output (I/O) terminal pads. When using a conventional wire bonding packaging technique, the pitch, or spacing between adjacent bonding wires becomes finer and finer as the number of I/O terminal pads increases for a given size die.

As known in the art, semiconductor die is typically sealed within a package of moldable material to protect it from environmental stresses. The moldable material is fed into cavities of a mold, thus flowing over the semiconductor die. The moldable material is then hardened to encapsulate the semiconductor die. However, the moldable material may bleed onto the solder mask. The mold bleed can adversely affect bonding of the external contacts to the bonding sites. The mold bleed can also adversely affect the electrical connections to the external contacts, and the cosmetic appearance of the package. Additionally, a subsequent process may be necessary to remove the mold bleed from the substrate surface and the equipment.

### SUMMARY OF THE INVENTION

In one aspect, the present invention provides a package substrate including a base layer and a dam structure or a dent structure on at least one side of the base layer. The base layer may be a CCL core, a molding compound, or an epoxy base.

In another aspect, the present invention provides a package substrate including a base layer having a first side and a second side that is opposite to the first side; a first solder mask on a first side of the base layer; and a second solder mask on a second side of the base layer, wherein at least one of the first and second solder masks has thereon a dam structure and a dent structure.

In accordance with another aspect of the invention, a chip package includes a package substrate having a chip mounting side and a bottom side that is opposite to the chip mounting side; a semiconductor chip mounted on the chip mounting side; and a dam structure and a dent structure on the bottom side of the package substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is schematic, cross-sectional diagram showing a germane portion of a package substrate in accordance with one embodiment of this invention.

FIG. 2 is a schematic, cross-sectional view of a window BGA package for DRAM chips in accordance with another embodiment of this invention.

### DETAILED DESCRIPTION

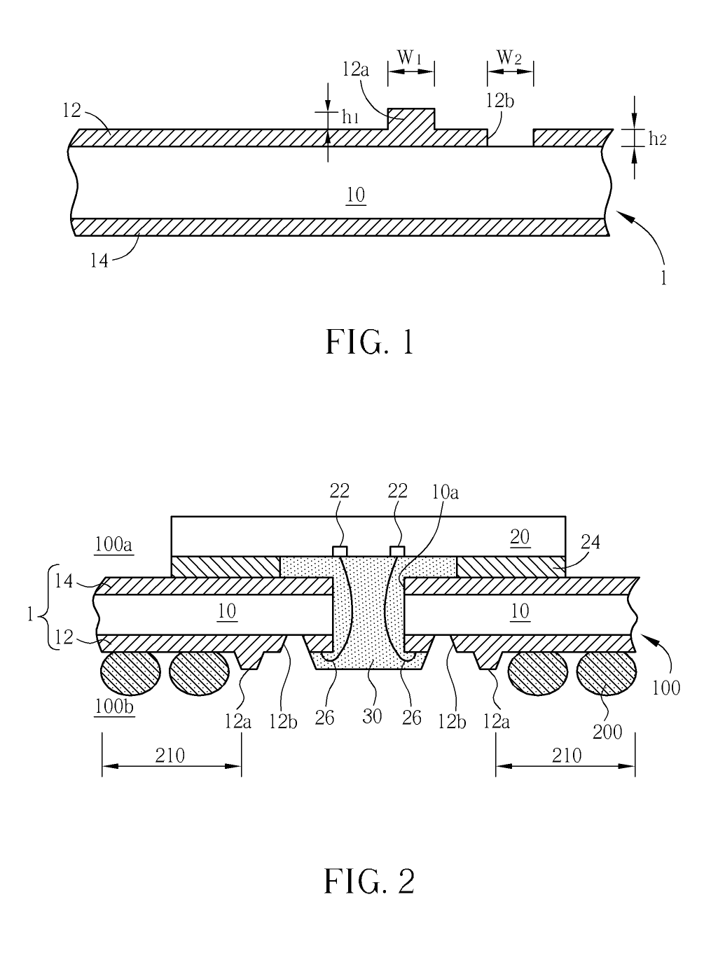

FIG. 1 is schematic, cross-sectional diagram showing a germane portion of a package substrate in accordance with one embodiment of this invention. As shown in FIG. 1, the package substrate 1 has a base layer 10 that may comprise a copper clay laminate (CCL) core and at least one layer of circuit pattern on the CCL core. The CCL core and the circuit pattern are not shown explicitly for the sake of simplicity. It is well known that circuit patterns on different sides of the core may be interconnected by plated through holes (PTHs), and that the package substrate 1 may comprise multiple layers of circuit patterns. It is to be understood that the package substrate 1 may be any other type of substrate, for example, a substrate merely composed of molding compound without using a CCL core or a solder mask. Alternatively, the base layer 10 may be an epoxy base.

According to the embodiment, a first solder mask 12 is provided on a first side of the base layer 10. A dam structure 12a may be formed on the first solder mask 12. The dam structure 12a protrudes from a major surface of the first solder mask 12 and may have a width w1 ranging, for example, between 0.001 mm and 2 mm, and a height h1 ranging, for example, between 0.001 mm and 2 mm. When viewed from the above, the dam structure 12a may have various shapes, for example, line shape, serpentine shape, or curved shape. It is to be understood that the dam structure 12a may be formed on a core material layer, a molding compound or a metal layer, depending upon the type of substrate chosen for the semiconductor package. Further, it is to be understood that in some cases the dam structure 12a may be made of a material that is different from that of the underlying layer (label 12). For example, the underlying layer 12 may be made of epoxy, CCL, BT resin, metal or solder mask, and is not limited to solder mask.

Optionally, a dent structure 12b may be provided adjacent to the dam structure 12a. The dent structure 12b may have a width w2 ranging, for example, between 0.001 mm and 2 mm, and a height h2 ranging, for example, between 0.001 mm and 2 mm. The dent structure 12b may have a shape selected from the group consisting of line shape, serpentine shape and curved shape. According to the embodiment, the dam structure 12a may be substantially in parallel with the dent structure 12b. The second side of the base layer 10 may be covered with a second solder mask 14. It is to be understood that although not shown in this figure, the aforesaid dam structure and/or dent structure may also be applied onto the second solder mask 14.

FIG. 2 is a schematic, cross-sectional view of an exemplary window BGA package for DRAM chips in accordance with another embodiment of this invention. As shown in FIG. 2, the chip package 100 comprises the package substrate 1 having the features substantially as described in FIG. 1. More specifically, the package substrate 1 has a chip mounting side 100a and a bottom side 100b that is opposite to the chip mounting side 100a. A semiconductor chip 20 such as a DRAM chip or die is mounted on the chip mounting side 100a by applying an adhesive layer 24 on the top surface of the second solder mask 14 to attach the semiconductor chip 20 on the chip mounting side 100a. In another embodiment, the label 24 may represent a bump, and no adhesive is used. In still another embodiment, the label 24 may represent both bump and adhesive. Likewise, the layer 14 may be made of epoxy, CCL, BT resin, metal or solder mask, and is not limited to solder mask.

An opening 10a, which is also referred to as “window”, is formed in the package substrate 1 between the chip mounting side 100a and the bottom side 100b. The active surface of the semiconductor chip 20 is electrically coupled to the bottom side 100b of the package substrate 1 using bond wires 26 that pass through the opening 10a. The bond wires 26 electrically connect the bond pads 22 on the active surface of the semiconductor chip 20 to the traces or bond fingers (not shown) on the bottom side 100b of the package substrate 1. The first solder mask 12 may provide electrical isolation and physical protection for the traces. It is to be understood that the layer 12 may be made of epoxy, CCL, BT resin, metal or solder mask, and is not limited to solder mask. A molding compound 30 is used to fill the opening 10a and encapsulate the bond pads 22, the bond wires 26, and the bond fingers on the bottom side 100b of the package substrate 1.

According to the embodiment, a dam structure 12a maybe formed on the first solder mask 12. The dam structure 12a protrudes from a major surface of the first solder mask 12. When viewed from the above, the dam structure 12a may have various shapes, for example, line shape, serpentine shape, or curved shape. Optionally, a dent structure 12b maybe provided adjacent to the dam structure 12a, and in this case, the dent structure 12b may be closer to the opening 10a than the dam structure 12a. The dent structure 12b in the first solder mask 12 can guide the mold bleed to a buffer area (not shown) during molding process. The dam structure 12a effectively stops and blocks the mold bleed from contaminating the solder ball implanting area 210, in which a plurality of solder balls 200 are disposed, on the other side of the dam structure 12a. The proposed structure also can prevent bleeding of paste-like materials. Further, although not shown in this figure, it is to be understood that the dam structure and/or the dent structure may be provided on the chip mounting side.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A package substrate, comprising:
a base layer having a first side and a second side that is opposite to the first side;
a first solder mask on a first side of the base layer; and
a second solder mask on a second side of the base layer, wherein at least one of the first and second solder masks has thereon a dam structure and/or a dent structure.

2. The package substrate according to claim 1 wherein the base layer comprises a CCL core and at least one layer of circuit pattern.

3. The package substrate according to claim 1 wherein the dam structure has a shape selected from the group consisting of line shape, serpentine shape and curved shape.

4. The package substrate according to claim 1 wherein the dam structure is arranged substantially in parallel with the dent structure.
